(19) United States
(12) Patent Application Publication
(10) Pub. No.: US 2002/0006701 A1
(43) Pub. Date: Jan. 17, 2002

(54) METHOD OF MANUFACTURING SEMICONDUCTOR DEVICE HAVING A THIN INSULATING FILM

(76) Inventor: HIROKI YAMAMOTO, KYOTO (JP)

Correspondence Address: MORGAN, LEWIS & BOCKIUS, 1800 M STREET NW, WASHINGTON, DC, 20036-5869, US

(21) Appl. No.: 09/359,880

(22) Filed: Jul. 26, 1999

(30) Foreign Application Priority Data
Jul. 27, 1998 (JP) 10-210991

(51) Int. Cl. H01L 21/336

(52) U.S. Cl. 438/257; 438/258; 438/263; 438/264

(57) ABSTRACT

After an oxide film 3 is formed on an Si wafer 2, a poly-Si layer 4a and a silicon nitride film 5a are formed and the oxide film 3 is thermally oxidized. Thus, the oxide film 3 is formed as a thick oxide film 3b at an area exclusive of the poly-Si layer 4a, whereas it is formed as a thin oxide film 3a at an area immediately beneath the poly-Si layer 4a (FIG. 2A). Thereafter, the silicon nitride film 5a is removed to form the poly-Si layer 7a which is electrically connected to the poly-Si layer 4a (FIGS. 2B and 2C). The poly-Si layer 4a and the poly-Si layer 7a are constituted by a floating gate 10. In this way, a reliable semiconductor device and its manufacturing method can be provided.

### BACKGROUND OF THE INVENTION

1. Field of the Invention

The present invention relates to a semiconductor device and a method of manufacturing it, and more particularly to a semiconductor device having a thin insulating film and a method of manufacturing it.

2. Description of the Related Art

FIG. 10 is a sectional view of EEPROM (Electrically Erasable PROM). As seen from FIG. 3, on the surface of a silicon (Si) wafer of EEPROM, a thin oxide film 13a and a thick oxide film 13b as an interlayer insulating film are formed. Electrons are tunneled between a floating gate 17a and a drain region 20 through the thin oxide film 13a so that they are taken in or out, thereby implementing write or erase of data. For these reasons, the thin oxide film 13a must be thin so as to allow electrons tunneling, and a thick oxide film 13b must be thick so as to be able to function as an insulating film.

Now referring to FIGS. 11A to 11C and 12A to 12D, an explanation will be given of a method of manufacturing the EEPROM. FIGS. 11A to 11C and 12A to 12D are sectional views in the direction orthogonal to the section of FIG. 10. First, with the upper surface of a silicon wafer 2 covered with a silicon nitride film (not shown), as shown in FIG. 11A, the surface of the Si wafer 2 is thermally-oxidized selectively to form LOCOS's(Local oxidized silicon) 21 and 22. After the LOCOS's 21 and 22 are formed, the silicon nitride film is removed. A drain region 20 is formed between the LOCOS's 21 and 22.

The surface of the Si wafer 2 is thermally oxidized to form an oxide film 13 between the LOCOS's 21 and 22 (FIG. 11B). The oxide film 13 is generally formed to have thickness of about 300-700 Å. With photoresists 18 and 19 formed on the oxide film 13, the oxide film corresponding to width L1 is removed by etching to expose the surface of the Si wafer 2 (FIG. 11C).

In the step shown in FIG. 11C, isotropic etching is used to prevent the surface of the Si wafer 2 exposed by etching from being damaged. If an anisotropic etching is used in this step, the surface of the Si wafer 2 will be damaged by bombardment of incident ions.

If the surface of the Si wafer is damaged, lattice defects occur which is attributable to disorder of the lattice of the Si wafer 2 This adversely affects the operation of a semiconductor device, thus deteriorating reliability of the semiconductor device. Therefore, the isotropic etching in which in contact with an etching solution, the oxide film 13 is removed through a chemical reaction is used, thereby preventing the surface of the Si wafer from being damaged.

Thereafter, the photoresists 18 and 19 are removed by exfoliation using sulfuric acid. (Exfoliation step using sulfuric acid comprises steps of immersing in sulfuric acid of 98 weight % for 20 minutes, washing by water for 10minutes, and then drying) FIG. 12 shows the state where the photoresists 18 and 19 have been removed. In this state, the thick oxide films 13 are left. The state as shown in FIG. 12 is thermally oxidized to form an oxide film having about 90 Å. As seen from FIG. 12B, a thin oxide film 13a having about 90 Å is formed between the thick oxide films 13b. After the thin oxide film 13a is formed, a polycrystalline silicon (poly-Si) layer 17 is formed on the resultant entire surface. The poly-Si layer 17 is doped with phosphorus(FIG. 12C). Using a mask, anisotropic etching is done to remove the poly-Si layer 17 so that the remaining portion is formed as a floating gate 17a.

The semiconductor device and its manufacturing method have the following problems. As described above, in the step shown in FIG. 11C, the isotropic etching was used to prevent the surface of the Si wafer from being damaged.

In the isotropic etching, etching advances isotropically in both vertically and horizontally. Therefore, the oxide film 13 is removed in a range with width L2 larger than the width L1 between the photoresists 18 and 19 (“undercut”). This makes the size of the thin oxide film 13a inaccurate, thus attenuating the reliability of the semiconductor device. It is a serious problem that operation characteristic is caused by such a size diversity of thin insulating film 13a corresponding to a region for writing or erasing.

Further, the photoresists 18 and 19 shown in FIG. 11C are removed by exfoliation using sulfuric acid so that the surface of the Si wafer 2 exposed from the thick oxide film 13b may be polluted while it is exposed to the sulfuric acid and polluted. The photoresists 18 and 19 contain the material of carbon family so that the surface of the Si wafer 2 may be polluted by the carbon family material. When the photoresists 18 and 19 are removed by exfoliation using sulfuric acid, foreign substance (residues of the photoresists 18 and 19) may be deposited on corners 14.

The pollution due to the sulfuric acid and carbon family material and deposition of the foreign substance on the corners attenuates the reliability of the semiconductor device.

### SUMMARY OF THE INVENTION

An object of the present invention is to provide a semiconductor device with high reliability and a method of manufacturing it.

A first object of the present invention is to define a region for writing or erasing data with high accuracy and to obtain an EEPROM with accurate characteristic.

A second object of the present invention is to provide a reliable semiconductor device having a thin insulating film region and thick insulating film region surrounding the thin insulating film and manufacturing thereof.

In order to attain the above object, in a method of manufacturing a semiconductor device according to a first aspect of the present invention, a thin insulating film is formed on a surface of a semiconductor substrate, and a first conductive portion is partially formed on the thin insulating film. The thin insulating film exclusive of its portion corresponding to the first conductive portion is formed into a thick insulating film, and a second conductive portion connected to said first conductive portion is formed on said first conductive portion and said thick insulating film.

In this way, the thin oxide film is formed on the semiconductor substrate, and formed as the thick oxide film so as to be exclusive of its portion on the first conductive portion. Therefore, in the step after the thin oxide film has been formed, the surface of the semiconductor substrate will not be exposed in order to obtain the thin oxide film. Therefore, pollutant or foreign substance will not be deposited on the surface of the semiconductor substrate, thereby providing a very reliable semiconductor device.

Since the second conductive portion is electrically connected to the first conductive portion which was used for forming the thin portion and thick portion of the insulating film, a reliable method of manufacturing a semiconductor device can be provided.

In the method for manufacturing a semiconductor device according to the second aspect of the present invention, a thin insulating film is formed on a surface of a semiconductor substrate, and a first conductive portion forming layer is formed on said thin insulating film. A growth suppressing portion forming layer is formed on said first conductive portion forming layer.

The first conductive portion forming layer and growth suppressing forming layer are anisotropically etched so that they remain partially, thereby forming the remaining portions as a first conductive portion and a growth suppressing portion.

Thereafter, the insulating film exclusive of its portion corresponding to the first conductive portion is grown to form a thick insulating film. The growth suppressing portion is removed from the top of the first conductive portion, and a second conductive portion electrically connected to the first conductive portion is formed on said first conductive portion and thick insulating film.

In this way, in order to form the first conductive portion and growth suppressing portion, the first conductive portion forming layer and the growth suppressing portion forming layer are removed by the anisotropic etching.

The anisotropic etching, unlike the isotropic etching in which etching advances isotropically in both vertical and horizontal direction, advances only in the vertical direction. Therefore, by using the anisotropic etching, the first conductive portion having an accurate width can be provided.

Using the first conductive portion, the insulating film is formed into the thick insulating film and thin insulating film so that the thin film having an accurate width can be formed, thereby providing a reliable semiconductor device.

With the growth suppressing portion located on the first conductive portion, the insulating film is grown to form the thick insulating film. Thus, the growth of the first conductive portion can be suppressed.

Further, the thin oxide film is formed on the semiconductor substrate, and formed as the thick insulating film so as to be exclusive of its portion on the first conductive portion. Therefore, in the step after the thin insulating film has been formed, the surface of the semiconductor substrate will not be exposed in order to obtain the thin insulating film. Therefore, pollutant or foreign substance will not be deposited on the surface of the semiconductor substrate, thereby providing a very reliable semiconductor device.

Since the surface of the semiconductor device is not exposed, although the anisotropic etching is used, the surface of the semiconductor substrate can be prevented from being damaged, thereby enhancing reliability of the semiconductor device.

Since the second conductive portion is electrically connected to the first conductive portion which was used to form the thin film and thick film on the insulating film, a reliable method of manufacturing a semiconductor device can be provided.

A third aspect of the method is a method of manufacturing a semiconductor device according to the second aspect, wherein the step of growing the second insulating film comprise a step of oxidizing a surface of the semiconductor substrate underlying the first insulating film by thermal oxidizing method.

A fourth aspect of the method is a method of manufacturing a semiconductor device according to the second aspect, wherein the step of growing the second insulating film comprises a step of forming a second insulating film on an entire surface by CVD and a step of removing the second insulating film formed on the growth suppressing portion by removing the growth suppressing portion by lift-off.

A fifth aspect of the method is a method of manufacturing a semiconductor device according to the second aspect, wherein the step of anisotropically etching comprises removing step only growth suppressing portion forming layer so as to remain the first conductive film, and the step of forming the second insulating film comprises a step of oxidizing the first conductive film exposed of the growth suppressing portion.

A sixth aspect of the method is a method of manufacturing a semiconductor device according to the fifth aspect, wherein the step of anisotropically etching comprises removing step growth suppressing portion forming layer and, a surface of the first conductive film to a constant depth and the step of forming the second insulating film comprises a step of oxidizing the first conductive film exposed of the growth suppressing portion.

A seventh aspect of the device is a semiconductor device which comprises: an insulating film formed on the surface of a semiconductor substrate and comprising a thin insulating region of a first insulating film and thick insulating region of the first insulating film and a second insulating film thereon, the thick insulating region surrounding the thin insulating region; a first conductive portion located on said first insulating film of the thin insulating region; a second conductive portion electrically connected to said first conductive portion.

Therefore, after the insulating thin film is formed on the surface of the semiconductor substrate, the first conductive potion is formed on the thin insulating film and using this first conductive portion, the thick film portion of the insulating film can be formed.

Therefore, in the step after the thin insulating film has been formed, the surface of the semiconductor substrate will not be exposed in order to obtain the thin insulating film. Therefore, pollutant or foreign substance will not be deposited on the surface of the semiconductor substrate, thereby providing a very reliable semiconductor device.

The second conductive portion is electrically connected to the first conductive portion. Where the first conductive portion is used to form the thin film portion and thick film portion in the insulating film, since the second conductive portion is connected to the first conductive layer, the semiconductor device can be effectively obtained.

An eight aspect of the device is a semiconductor device according to the seventh aspect: wherein the semiconductor device comprises a EEOROM which comprises; a drain region formed in the semiconductor substrate; a floating gate of the first conductive portion formed on the drain region through the thin insulating region and the second conductive portion connected to the first conductive portion; and a control gate formed on the floating gate through a thin third insulating film.

The above and other objects and features of the present invention will be more apparent from the following description taken in conjunction with the accompanying drawings.

### BRIEF DESCRIPTION OF THE DRAWINGS

FIGS. 1A to 1D are side sectional views showing a method of manufacturing an EEPROM of a first embodiment according to the present invention;

FIGS. 2A to 2C are side sectional views showing a method of manufacturing an EEPROM of a first embodiment according to the present invention;

FIG. 3 is a planar view of an EEPROM of a first embodiment;

FIG. 4 is an X-X sectional view of FIG. 3;

FIGS. 5A to 5D are side sectional views showing a method of manufacturing an EEPROM of a second embodiment according to the present invention;

FIGS. 6A to 6C are side sectional views showing a method of manufacturing an EEPROM of a second embodiment according to the present invention;

FIGS. 7A to 7D are side sectional views showing a method of manufacturing an EEPROM of a third embodiment according to the present invention;

FIGS. 8A to 8C are side sectional views showing a method of manufacturing an EEPROM of a third embodiment according to the present invention;

FIGS. 9A to 9C are side sectional views showing a method of manufacturing an EEPROM of a fourth embodiment according to the present invention;

FIG. 10 is a side sectional view of a conventional EEPROM;

FIGS. 11A to 11C are side sectional views showing a method of manufacturing the conventional EEPROM shown in FIG. 3; and

FIGS. 12A to 12D are side sectional views showing a method of manufacturing the conventional EEPROM shown in FIG. 3.

### DESCRIPTION OF THE PREFERRED EMBODIMENTS

An explanation will be given of an embodiment of the semiconductor device and its manufacturing method according to the present invention. In this embodiment, an EEPROM is exemplified as a semiconductor device.

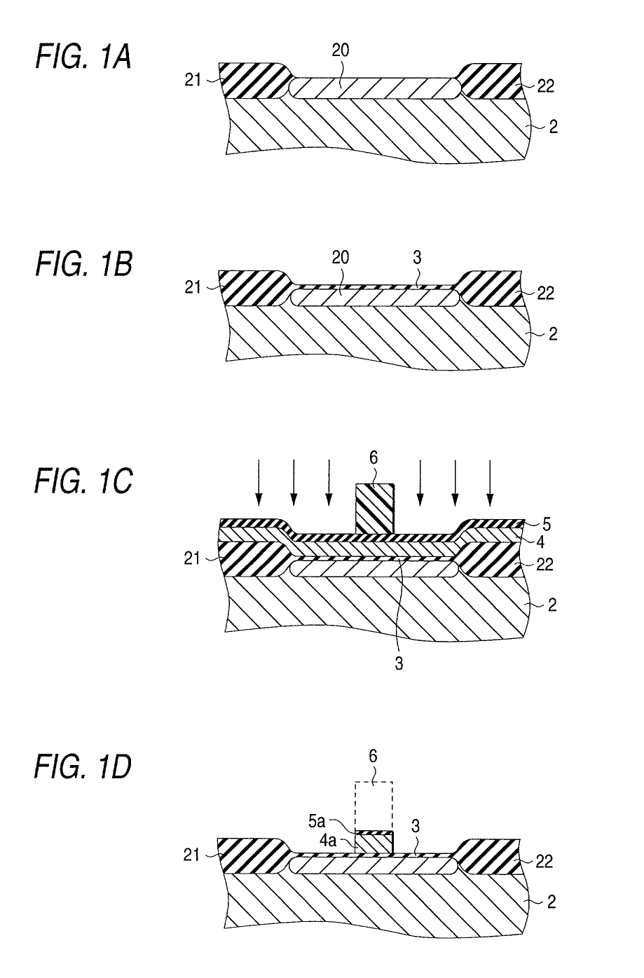

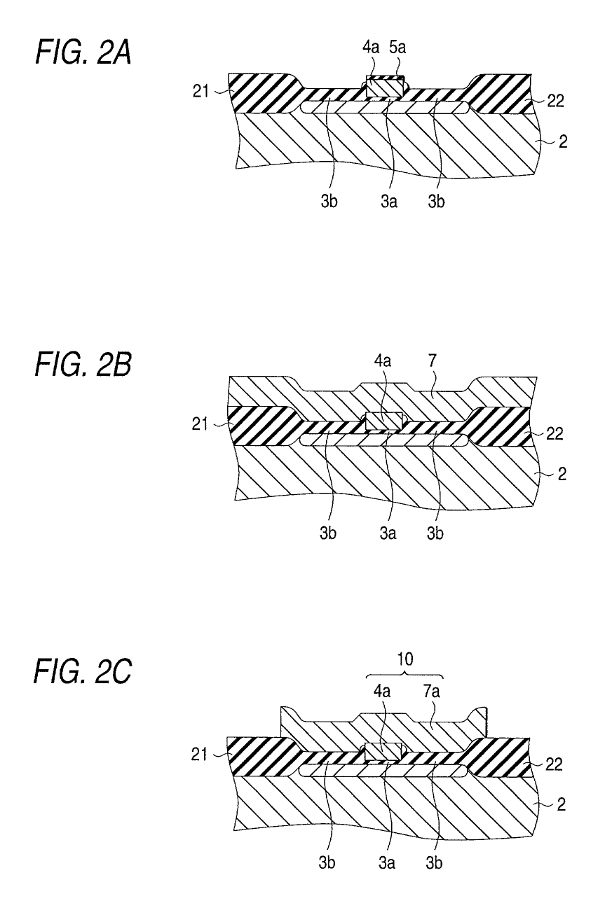

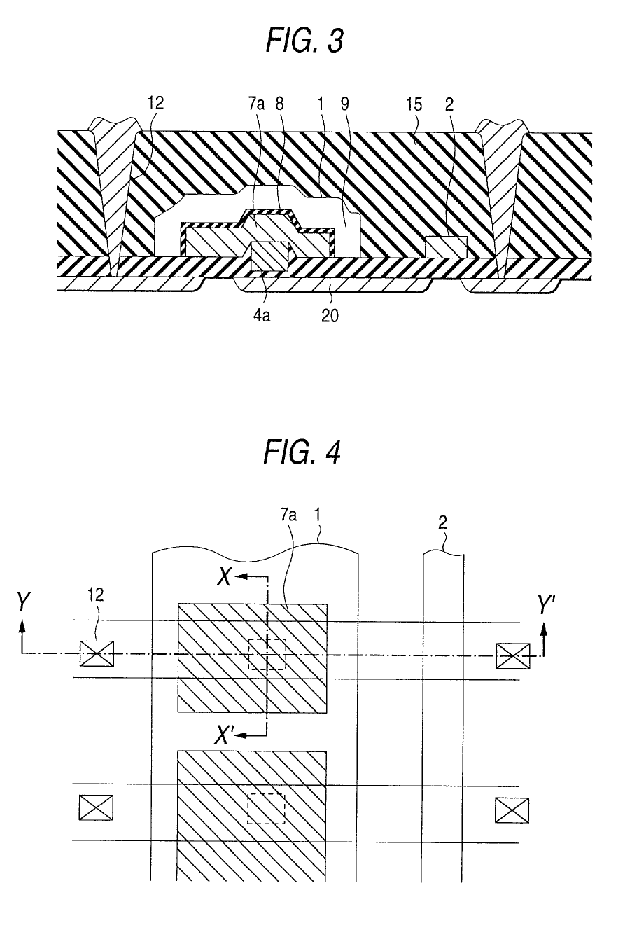

Referring to FIGS. 1, 2, 3, and 4, a method of manufacturing the EEPROM will be described. FIGS. 3 and 4 show the EEPROM which is manufactured by the method of the embodiment of the invention. FIGS. 1A-1D and FIGS. 2A-2C are sectional views in the direction orthogonal to the section of FIG. 3. FIG. 3 is a sectional view taken along the line Y-Y′ of FIG. 4, and FIGS. 1 and 2 are views showing a section taken along the line X-X′ of FIG. 4.

The EEPROM is configured in the following manner. A drain region 20 constituted by an n-type diffusion layer is formed in a device region surrounded by LOCOS's 21 and 22 which are formed on the surface of a p-type silicon wafer 2 serving as a semiconductor substrate. A first poly-Si layer 4a is formed on the surface of the drain region 20 via an insulating film 3a which is so thin that tunneling can be performed through the film. A floating gate 10 is formed by the first poly-Si layer 4a and a second poly-Si layer 7a which is formed on the first poly-Si layer. A control gate 9 is formed on the floating gate via an insulating film 8. The thin insulating film 3a is surrounded by a thick insulating film 3b. The area of the thin insulating film 3a defines a data writing and reading region. In the thin insulating film 3a, formation of a thick oxide film is suppressed by the pattern of an oxidation preventing film which covers the first poly-Si layer 4a, and the pattern control is accurately performed.

Next, steps of manufacturing an EEPROM of a second embodiment of the invention will be described.

First, with the upper surface of a p type of silicon (Si) wafer 2 served as a semiconductor substrate, partially covered with a silicon nitride film (not shown), as shown in FIG. 1A, the surface of the Si wafer 2 is thermally-oxidized selectively to form LOCOS's 21 and 22. After the LOCOS's 21 and 22 are formed, the silicon nitride film is removed. A drain region(n-type) 20 is formed between the LOCOS's 21 and 22.

Thereafter, the surface of the Si wafer 2 is thermally oxidized to form an oxide film 3 which is an insulating film between the LOCOS's 21 and 22 (FIG. 1B). In this embodiment, the thin oxide film 3 of about 90 Å is formed. By the CVD (Chemical Vapor Deposition) technique, a poly-Si layer 4 which serves as a first conductive portion forming layer is deposited. Likewise, by the CVD technique, a silicon nitride film 4 which serves as a growth-suppressing portion forming layer is deposited on the poly-Si layer 4 (FIG. 1C).

Thereafter, in order that the poly-Si layer 4 and silicon nitride film 5 remain partially, a photoresist 6 is formed as a mask on the silicon nitride film 5. The areas of the poly-Si layer and silicon nitride film 5 exclusive of the remaining portions are removed by reactive ion etching(RIE) . The state after the poly-Si layer 4 and silicon nitride film 5 have been removed by anisotropic etching is shown in FIG. 1D. After etching, the photoresist is removed.

The remaining poly-Si layer 4 is formed as a poly-Si layer 4a which serves as a first conductive portion, and the remaining silicon nitride film 5 is formed as a silicon nitride film 5a which serves as a growth suppressing film.

The anisotropic etching, unlike the isotropic etching in which etching advances isotopically in both vertical and horizontal direction, advances only in the vertical direction, so that the poly-Si layer 4a having an accurate width.

Next, through the oxide film 3, a surface of the silicon wafer is thermally oxidized. Specifically, as seen from FIG. 2A, the oxide film 3 at an area exclusive of the poly-Si layer 4a is grown to form a thick oxide film 3b which is a thick insulating film. In this embodiment, the thick oxide film 3b is formed to have a thickness of about 500 Å. The oxide film 3 corresponding to the poly-Si layer 4a is not oxidized nor grown so that the oxide film 3 immediately beneath the poly-Si layer is formed as a thin oxide film 3a which is an thin insulating film.

Incidentally, the oxidation/growth of the poly-Si layer 4a is suppressed by the silicon nitride film 5a. In the step of FIG. 1C, the poly-Si layer 4a having an accurate width has been formed so that the thin oxide film 3a immediately beneath the poly-Si layer 4a can be also formed to have an accurate width.

In the steps as shown in FIGS. 1C and 1D, the anisotropic etching have been carried out. The anisotropic etching makes ion-etching using bombardment of incident ions. Therefore, when incident ions are brought into direct contact with the surface of the Si wafer 2, the Si wafer 2 may be damaged due to the ion bombardment.

In this embodiment, however, the oxide film 3 is located on the surface of the Si wafer 2, the incident ions are not brought into direct contact with the surface of the Si wafer 2. This prevents the surface of the Si wafer 2 from being damaged, thereby enhancing the reliability of the semiconductor device.

As described above, in this embodiment, the oxide film 3 has been formed as a thin film having a thickness of about 90 Å. Therefore, owing to the incident ions in the anisotropic etching, the surface of the Si wafer 2 may be damaged through the thin oxide film 3. However, in the step shown in FIG. 2A, the oxide film 3 is oxidized and grown so that the damaged layer on the surface of the Si wafer 2 is also oxidized and formed as the thick oxide film 3b.

Thereafter, the damage of the surface of the Si wafer 2 can be dissolved, thereby improving reliability of the semiconductor device.

Where lattice defects occur which is attributable to the disorder of the lattice of the Si wafer 2 owing to damaging by the anisotropic etching, they can be dissolved by heating in thermal oxidation in the step of FIG. 2A, thereby enhancing the reliability of the semiconductor device.

After the thin oxide film 3a and thick oxide film 3b as shown in FIG. 2A are formed, the silicon nitride film 5a is removed using hot phosphorus acid. Thereafter, by the CVD technique, a poly-Si layer 7 is deposited on the entire surface inclusive of the poly-Si layer 4a and thick oxide film 3b (FIG. 2B). In this embodiment, the poly-Si layer 7 having a thickness of about 3000 Å is formed.

After the poly-Si layer 7 has been formed, it is doped with impurities (phosphorus) through the poly-Si layer 7. The doped impurities reach the poly-Si layer 4a through the poly-Si layer 7. With photoresist partially formed on the poly-Si layer 7 (not shown), the poly-Si layer 7 is partially removed by the anisotropic etching so that the remaining portion is formed as a poly-Si layer 7a as shown in FIG. 2C.

The poly-Si layer 4a and poly-Si layer 7a are electrically connected to each other to constitute a floating gate 10. The poly-Si layer 7a is connected to the poly-Si layer 4a which was used to form the thin oxide film 3a and the thick oxide film 3b so that the floating gate 10 is constituted, thereby providing an efficient manufacturing method.

Thereafter thin insulating film 8 and control gate 9 are formed thereon, and silicon oxide film as an interlayer insulating film 15 is formed. Further contact hole 12 and so on are formed in the interlayer insulating film 15, and then EEPROM shown by FIGS.3 and 4.

As described above, in this embodiment, the thin oxide film 3 is formed on the Si wafer 2, and the area exclusive of the poly-Si layer 4a on the thin oxide film 3 is formed as the thick oxide film 3b. Therefore, in the step after the thin oxide film 3 has been formed, the surface of the Si wafer 2 will not be exposed in order to obtain the thin oxide film 3a. Therefore, pollutant or foreign substance will not be deposited on the surface of the Si wafer, thereby providing a very reliable semiconductor device.

The semiconductor device and its manufacturing method according to the present invention should not be limited to the embodiments described above. In this embodiment, the oxide film 3 and thin oxide film 3a each having a thickness of about 90 Å have been exemplified. They may be thinner or thicker than about 90 Å as long as they are thinner than the thick oxide film 3b.

In the embodiment described above, the thick oxide film 3b having a thickness of about 500 A was exemplified, but may be thicker or thinner than about 500 Å. Further, in the embodiment described above, the poly-Si layer 7 having a thickness of about 3000 Å was exemplified, but may be thicker or thinner than about 3000 Å.

In the embodiment described above, thick insulating region is formed by oxidizing the surface of the silicon wafer underlying the oxide film by thermal oxidizing. Instead of such a process, it can be taken that after depositing a thick insulating film by CVD, silicon oxide formed on the growth suppressing film is be removed by lift-off process.

In the embodiment described above, the present invention was applied to EEPROM exemplified as a semiconductor device. However, the present invention can be applied to a semiconductor device having an insulating film composed of an thin film and thick film in which a first conductive portion is located on the thin film portion and a second conductive portion is electrically connected to the second conductive portion.

Embodiment 2

Next, steps of manufacturing an EEPROM of a second embodiment of the invention will be described.

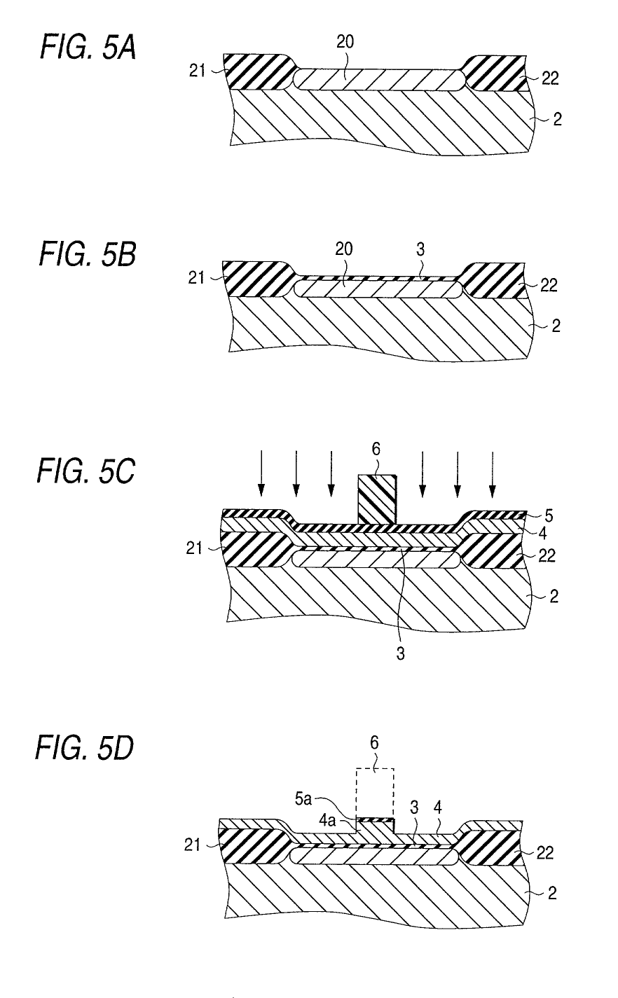

First, after the same steps as those of the first embodiment shown in FIGS. 1A to 1C, steps of FIGS. 5A to 5C are conducted to form the photoresist 6 as a mask on the silicon nitride film 5.

In the first embodiment described above, the poly-Si layer 4 and the silicon nitride film 5 exclusive of the remaining portions are then removed by anisotropic etching. In this method, only parts of the silicon nitride film 5 and the poly-Si layer 4 are subjected to anisotropic etching, so that a part of the poly-Si layer 4 remains on the surface of the substrate as shown in FIG. 5D. After etching, the photoresist 6 is removed.

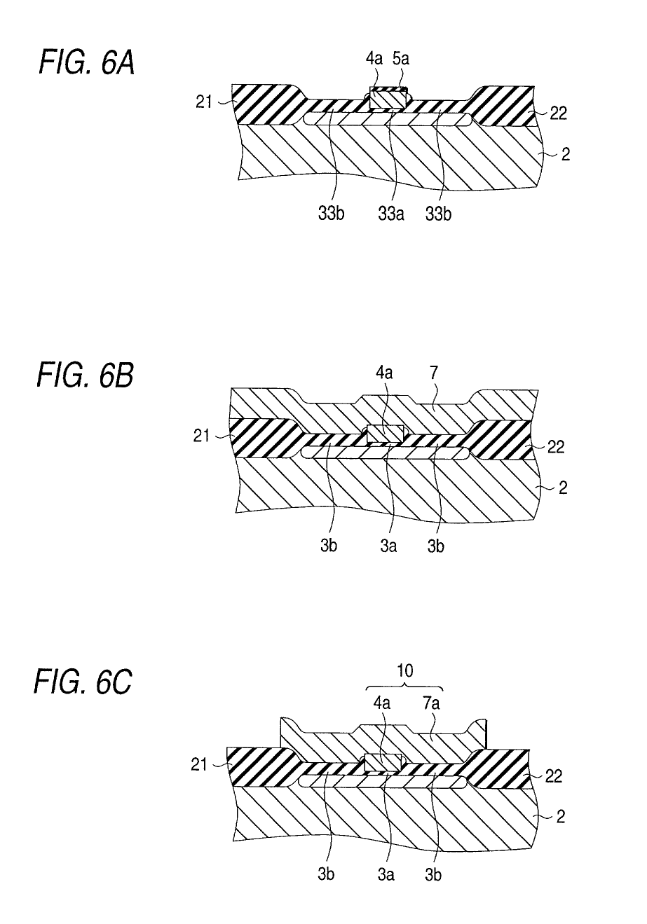

The remaining poly-Si layer 4 is formed as the poly-Si layer 4a which serves as a first conductive portion, and the remaining silicon nitride film 5 is formed as the silicon nitride film 5a which serves as a growth suppressing film. Next, thermal oxidation is conducted under this state, whereby an oxide film 33b is further formed on the oxide film 3, so that the thick oxide film 33b which is a thick insulating film is formed at an area exclusive of the poly-Si layer 4a as shown in FIG. 6A.

Thereafter, the silicon nitride film 5a is removed, and the poly-Si layer 7 is formed (FIG. 6B). The poly-Si layer is then patterned (FIG. 6C).

Embodiment 3

Next, steps of manufacturing an EEPROM of a third embodiment of the invention will be described.

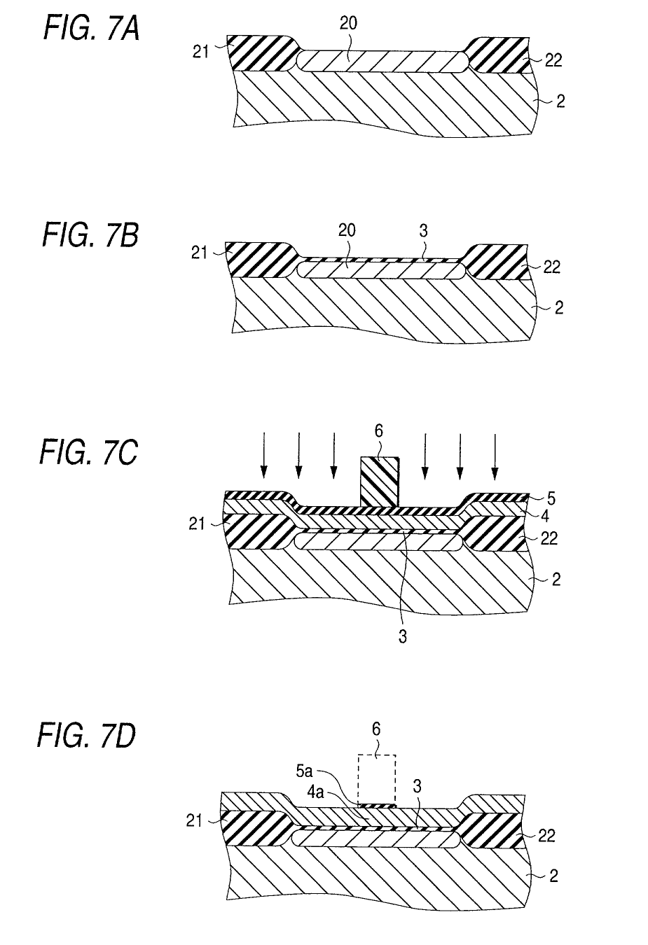

First, after the same steps as those of the first embodiment shown in FIGS. 1A to 1C and the second embodiment shown in FIGS. 5A to 5C, steps of FIGS. 7A to 7C are conducted to form the photoresist 6 as a mask on the silicon nitride film 5.

In the second embodiment described above, a part of the poly-Si layer 4 exclusive of the remaining portions is then caused to remain as a result of anisotropic etching. In this embodiment, only the silicon nitride film 5 is removed, and the poly-Si layer remains as it is on the surface of the substrate as shown in FIG. 7D. After etching, the photoresist 6 is removed.

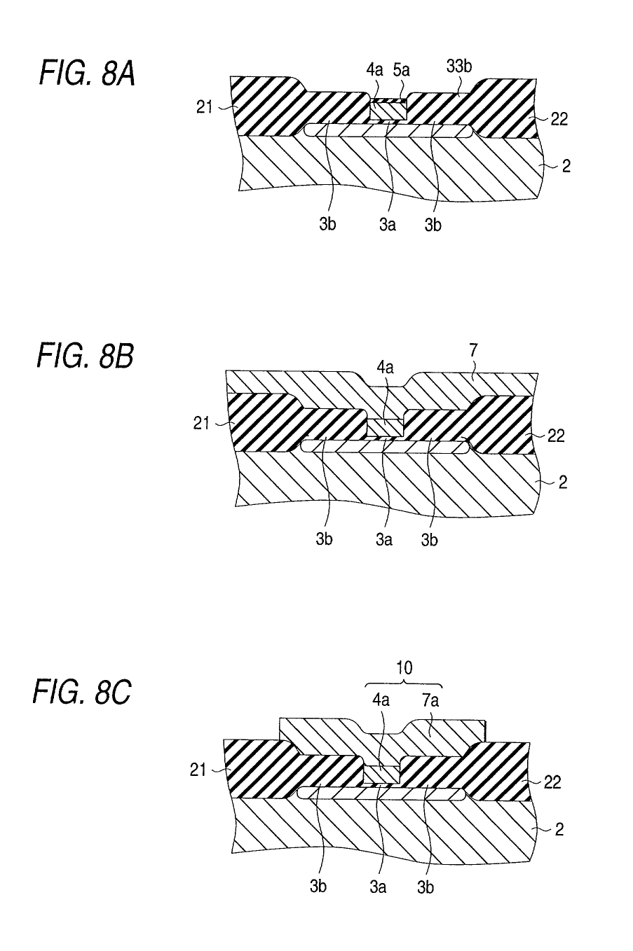

The remaining poly-Si layer 4 is formed as the poly-Si layer 4a which serves as a first conductive portion, and the remaining silicon nitride film 5 is formed as the silicon nitride film 5a which serves as a growth suppressing film. Next, thermal oxidation is conducted under this state, whereby the oxide film 33b is further formed on the oxide film 3, so that the thick oxide film 33b which is a thick insulating film is formed at an area exclusive of the poly-Si layer 4a as shown in FIG. 8A.

Thereafter, the silicon nitride film 5a is removed, and the poly-Si layer 7 is formed (FIG. 8B). The poly-Si layer is then patterned (FIG. 8C). The oxidation/growth of the poly-Si layer 4a is suppressed by the silicon nitride film 5a. Furthermore, an insulating film having less film distortion can be formed although the accuracy of the size of the data writing region is lower than that in the case where, as in the first embodiment, the poly-Si layer 4a having an accurate width is formed by anisotropic etching in the step of FIG. 1C.

Embodiment 4

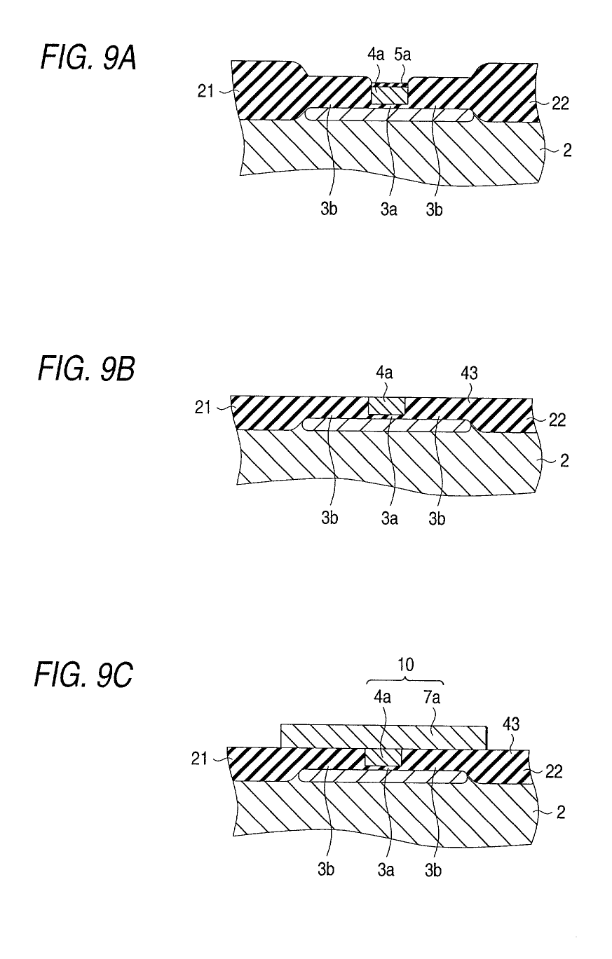

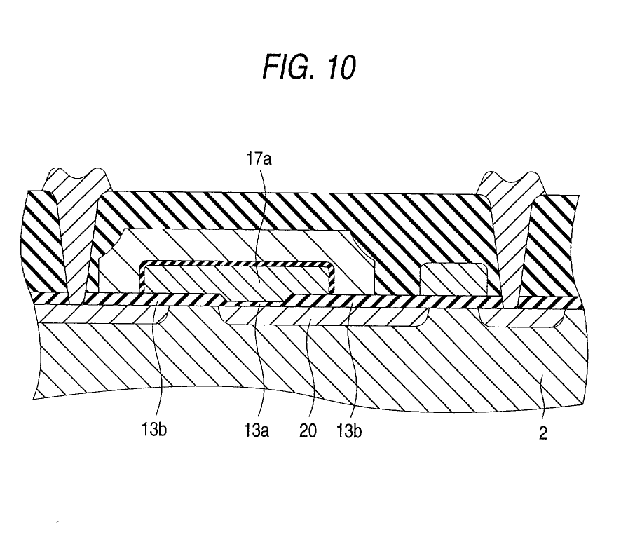

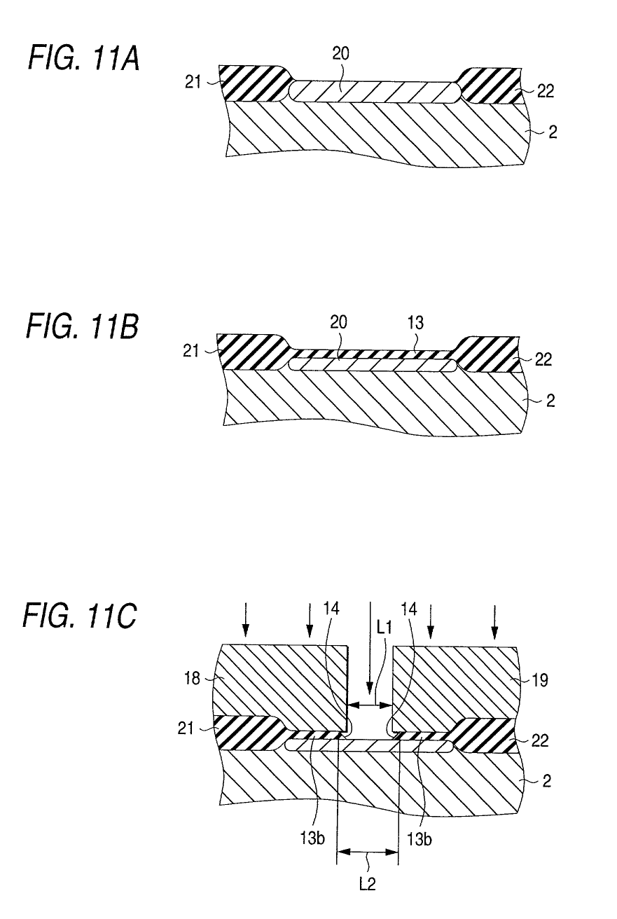

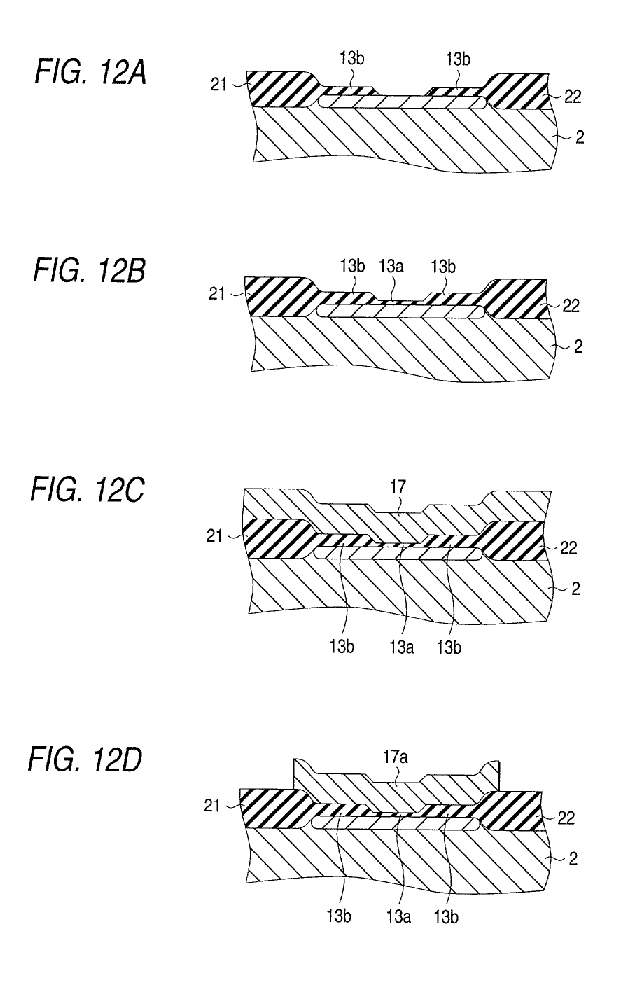

Next, steps of manufacturing an EEPROM of a fourth embodiment of the invention will be described with reference to FIGS. 9A to 9C.

In the third embodiment shown in FIGS. 8A to 8C, the thick oxide film 33b is formed by thermal oxidation to a level which is higher than the poly-Si layer 4a. By contrast, in this embodiment, the oxide film is removed to the level of the poly-Si layer 4a, by surface planarization using a chemical polishing method or the like, so that the surface of the oxide film is flush with the poly-Si layer 4a as shown in FIG. 9B. The subsequent steps are conducted in the same manner as those of the other embodiments. According to this configuration, the surface can be flattened, and subsequent processes such as formation of contact holes can be performed accurately. A structure in which an erasing gate is disposed has a problem in that a large step must be formed. By contrast, in this method, the portions below the control gate can be formed without forming a step. Therefore, this method is particularly effective.

In this method, when the formation is performed by means of etch back or the like, it is not always necessary to interpose the silicon nitride film which serves as a growth suppressing film.

In this way, an EEPROM with high reliability can be produced. It is a matter of course that the invention can be applied not only to an EEPROM and also to other semiconductor devices.

What is claimed is:

1. A method of manufacturing a semiconductor device comprising the steps of:
forming a first insulating film on a surface of a semiconductor substrate;
forming a first conductive portion partially on the first insulating film;
forming a second insulating film exclusive of its portion corresponding to the first conductive portion into an insulating region; and
forming a second conductive portion on said first conductive portion and said insulating region, said second conductive portion being connected to said first conductive portion.

2. A method of manufacturing a semiconductor device comprising the steps of:
forming a first insulating film on a surface of a semiconductor substrate;
forming a first conductive forming layer on said first insulating film;
forming a growth suppressing portion forming layer on said first conductive portion forming layer;
anisotropically etching said first conductive portion forming layer and growth suppressing portion forming layer so that they remain partially, thereby forming the remaining portions as a first conductive portion and a growth suppressing portion;
growing a second insulating film exclusive of its portion corresponding to the first conductive portion to form an insulating region;
removing said growth suppressing portion from the top of the first conductive portion; and
forming a second conductive portion on said first conductive portion and the insulating region, said conductive portion being electrically connected to say first conductive portion.

3. A method of manufacturing a semiconductor device according to claim 2, wherein the step of growing the second insulating film comprise a step of oxidizing a surface of the semiconductor substrate underlying the first insulating film by thermal oxidizing method.

4. A method of manufacturing a semiconductor device according to claim 2, wherein the step of growing the second insulating film comprises a step of forming a second insulating film on an entire surf ace by CVD and a step of removing the second insulating film formed on the growth suppressing portion by removing the growth suppressing portion by lift-off.

5. A method of manufacturing a semiconductor device according to claim 2, wherein the step of anisotropically etching comprises removing step only growth suppressing portion forming layer so as to remain the first conductive film, and
the step of forming the second insulating film comprises a step of oxidizing the first conductive film exposed of the growth suppressing portion.

6. A method of manufacturing a semiconductor device according to claim 5, wherein the step of anisotropically etching comprises removing step growth suppressing portion forming layer and,
a surface of the first conductive film to a constant depth and the step of forming the second insulating film comprises a step of oxidizing the first conductive film exposed of the growth suppressing portion.

7. A semiconductor device comprising:
an insulating film formed on the surface of a semiconductor substrate and comprising a thin insulating region of a first insulating film and thick insulating region of the first insulating film and a second insulating film thereon, the thick insulating region surrounding the thin insulating region
a first conductive portion located on said first insulating film of the thin insulating region;
a second conductive portion electrically connected to said first conductive portion.

8. A semiconductor device according to claim 7: wherein the semiconductor device comprises a EEOROM which comprises;
a drain region formed in the semiconductor substrate;
a floating gate of the first conductive portion formed on the drain region through the thin insulating region and the second conductive portion connected to the first conductive portion; and
a control gate formed on the floating gate through a thin third insulating film.
